(19) United States
(12) Patent Application Publication
(10) Pub. No.: US 2020/0105954 A1
(43) Pub. Date: Apr. 2, 2020

(54) SOLAR CELL MODULE INCLUDING A PLURALITY OF SOLAR CELLS CONNECTED AND METHOD OF MANUFACTURING A SOLAR CELL MODULE

(71) Applicant: PANASONIC CORPORATION, Osaka (JP)

(72) Inventors: Kenichi MAKI, Osaka (JP); Haruhisa HASHIMOTO, Osaka (JP); Naoto IMADA, Osaka (JP)

(21) Appl. No.: 16/560,872

(22) Filed: Sep. 4, 2019

(30) Foreign Application Priority Data
Sep. 28, 2018 (JP) 2018-185514

(51) Int. Cl. H01L 31/048; H01L 31/0224; H01L 31/05; H01L 31/02; H02S 30/10; B32B 17/10

(52) U.S. Cl. CPC H01L 31/048; H01L 31/022441; B32B 17/10; H01L 31/02013; H02S 30/10; H01L 31/0516

(57) ABSTRACT

The second bridge wiring member includes a surface having a length in the first direction and a width in the second direction. A plurality of first cell wiring members extending from the 1-8th solar cell toward the second bridge wiring member and a plurality of second cell wiring members extending from the 2-8th solar cell toward the second bridge wiring member are connected to the surface of the second bridge wiring member such that the plurality of first cell wiring members and the plurality of second cell wiring members mutually overlap along the second direction.

### CROSS-REFERENCE TO RELATED APPLICATION

This application is based upon and claims the benefit of priority from the prior Japanese Patent Application No. 2018-185514, filed on Sep. 28, 2018, the entire contents of which are incorporated herein by reference.

### BACKGROUND

### 1. Field

The disclosure relates to a solar cell module and, more particularly, to a solar cell module including a plurality of solar cells and a method of manufacturing a solar cell module.

### 2. Description

A solar cell module includes a plurality of solar cells. A solar cell is available as a cell of a standard size (156 mm×156 mm) and a half-cut cell of a size (156 mm×78 mm) half the standard size. When a half-cut cell is used, a plurality of solar cells are grouped into, for example, two sections, and three solar cell strings are included in each section. Further, the two sections are connected in parallel by being connected to a bridge wiring member at the central portion (see, for example, http://www.js-ge.cn/product.asp?Product_ID=321&classid=69)

A wire film configured by connecting two transparent members by a plurality of wires may be used to simplify the manufacturing of a solar cell module. In the case a wire film is used in a solar cell module, the two transparent members are adhesively attached to adjacent solar cells respectively, and the wires are used as wiring members. In this configuration, the plurality of wires extending from the solar cells provided at the end of the solar cell string are connected to the bridge wiring member. Generally, the wire is configured to be thinner than a tab wire so that the area of contact between the wire of the solar cell and the bridge wiring member will be smaller. A smaller area of contact results in an increase in the electric resistance and reduced strength of connection.

### SUMMARY

The disclosure addresses the above-described issue, and a general purpose thereof is to provide a technology of increasing an area of contact between a solar cell and a bridge wiring member.

A solar cell module according to an embodiment of the present disclosure includes: a bridge wiring member that extends in a first direction; a first solar cell string that extends, of a first region and a second region separated and interfaced by the bridge wiring member, in the first region and in a second direction different from the first direction; and a second solar cell string that extends in the second region and in the second direction. The bridge wiring member includes a surface having a length in the first direction and a width in the second direction. The first solar cell string includes a first solar cell provided on a side of the bridge wiring member. The second solar cell string includes a second solar cell provided on a side of the bridge wiring member and facing the first solar cell, sandwiching the bridge wiring member. A plurality of first cell wiring members extending from the first solar cell toward the bridge wiring member and a plurality of second cell wiring members extending from the second solar cell toward the bridge wiring member are connected to the surface of the bridge wiring member such that the first cell wiring members and the second cell wiring members mutually overlap along the second direction.

Another embodiment of the present disclosure relates to a manufacturing method. The method is for manufacturing a solar cell module including: a bridge wiring member that extends in a first direction; a first solar cell string that extends, of a first region and a second region separated and interfaced by the bridge wiring member, in the first region and in a second direction different from the first direction; and a second solar cell string that extends in the second region and in the second direction. The bridge wiring member includes a surface having a length in the first direction and a width in the second direction. The first solar cell string includes a first solar cell provided on a side of the bridge wiring member. The second solar cell string includes a second solar cell provided on a side of the bridge wiring member and facing the first solar cell, sandwiching the bridge wiring member. The method includes: removing at least one of a first film and a second film, the first film being configured by attaching a first cell film at a first end of the plurality of first cell wiring members and attaching a first wiring member film at a second end of the plurality of first cell wiring members, and the second film being configured by attaching a second cell film at a first end of the plurality of second cell wiring members and attaching a second wiring member film at a second end of the plurality of second cell wiring members; attaching the first cell film to the first solar cell and attaching the second cell film to the second solar cell; and connecting a second end of the plurality of first cell wiring members and a second end of the plurality of second cell wiring members to a surface of the bridge wiring member such that the plurality of first cell wiring members and the plurality of second cell wiring members mutually overlap along the second direction.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a plan view of a solar cell module according to embodiment 1;

FIG. 2 is a cross sectional view showing the structure of the solar cell module of FIG. 1;

FIG. 3 is a perspective view showing the structure of a film used in the solar cell module of FIG. 2;

FIG. 4 is an enlarged plan view showing the structure of a portion of the solar cell module of FIG. 1;

FIGS. 5A-5B are plan views showing the structure of the film used in the solar cell module of FIG. 4;

FIG. 6 is an enlarged plan view showing the structure of a portion of the solar cell module according to embodiment 2; and

FIG. 7 is an enlarged plan view showing the structure of a portion of the solar cell module according to embodiment 3.

### DETAILED DESCRIPTION

The invention will now be described by reference to the preferred embodiments. This does not intend to limit the scope of the present invention, but to exemplify the invention.

### Embodiment 1

A brief summary will be given before describing the disclosure in specific details. Embodiment 1 relates to a solar cell module in which a plurality of solar cells are arranged in a matrix. An encapsulant is provided between the first protection member and the second protection member in the solar cell module. The encapsulant encapsulates a plurality of solar cell. In this process, the two adjacent solar cells are connected by a wire film. As described above, a wire film is configured as two transparent members connected by a plurality of wires, and the respective transparent members are adhesively attached to adjacent solar cells. Since the wire plays the role of a wiring member, a solar cell string is formed by connecting a plurality of solar cells arranged in a direction of extension of the wire by means of a plurality of wire films. A wire film like this is used to simplify the manufacturing of a solar cell module.

Meanwhile, a half-cut cell may be used as a solar cell, and a bridge wiring member may be provided at the central portion. In this configuration, a solar cell string is provided in each of two regions separated and interfaced by the bridge wiring member (hereinafter, the two separated regions will be referred to as “first region” and “second region”, respectively), and the end of each solar cell string is connected to the bridge wiring member. To describe it more specifically, the solar cell provided at the end of the solar cell string in the first region and the solar cell provided at the end of the solar cell in the second region face each other, sandwiching the bridge wiring member, and a plurality of wires from the respective solar cell are connected to the bridge wiring member. In such a connection, it is required to prevent interference between the plurality of wires from the respective solar cells to establish contact between the wire and the bridge wiring member. Therefore, the wires on the bridge wiring member are configured to have a small length, for example.

By reducing the length of the wires on the bridge wiring member, however, the area of contact between the wires of the solar cell and the bridge wiring member is reduced. Further, the wire is thinner than the related-art tab wire so that the area of contact is further reduced. As a result, the electric resistance is increased, and the strength of connection is reduced. This embodiment addresses the issue of an increase in the electric resistance by causing the plurality of wires from the respective solar cells to be in mesh with each other in a comb tooth pattern on the bridge wiring member without configuring the wires to have a small length. The terms “parallel” and “perpendicular” in the following description not only encompass completely parallel or perpendicular but also encompass off-parallel and off-perpendicular within the margin of error. The term “substantially” means identical within certain limits.

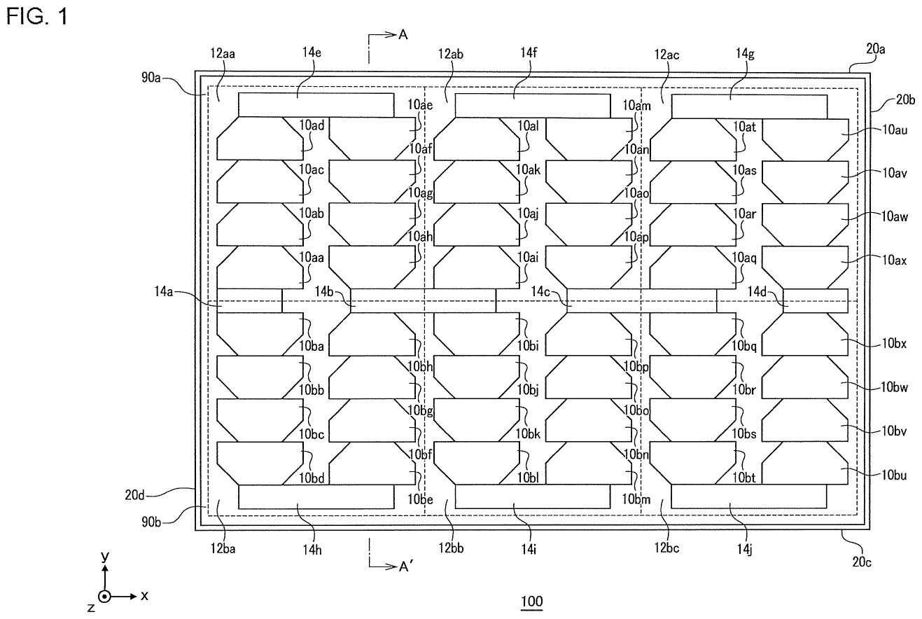

FIG. 1 is a plan view of a solar cell module 100. As shown in FIG. 1, a rectangular coordinate system formed by an x axis, y axis, and z axis is defined. The x axis and y axis are orthogonal to each other in the plane of the solar cell module 100. The z axis is perpendicular to the x axis and y axis and extends in the direction of thickness of the solar cell module 100. The positive directions of the x axis, y axis, and z axis are defined in the directions of arrows in FIG. 1, and the negative directions are defined in the directions opposite to those of the arrows. Of the two principal surfaces forming the solar cell module 100 that are parallel to the x-y plane, the principal surface disposed on the positive direction side along the z axis is the light receiving surface, and the principal surface disposed on the negative direction side along the z axis is the back surface. Hereinafter, the positive direction side along the z axis will be referred to as “light receiving surface side” and the negative direction side along the z axis will be referred to as “back surface side”. When the x axis direction is referred to as the “first direction”, the y axis direction is referred to as the “second direction”. Therefore, FIG. 1 can be said to be a plan view of the solar cell module 100 as viewed from the light receiving surface side.

The solar cell module 100 includes a 1-1-st solar cell 10aa, . . . , a 1-24th solar cell 10ax, a 2-1-st solar cell 10ba, . . . , a 2-24th solar cell 10bx, which are generically referred to as solar cells 10, a first bridge wiring member 14a, . . . , a tenth bridge wiring member 14j, which are generically referred to as bridge wiring members 14, a first frame 20a, a second frame 20b, a third frame 20c, and a fourth frame 20d, which are generically referred to as frames 20.

The first frame 20a extends in the x axis direction, and the second frame 20b extends in the negative direction along the y axis from the positive direction end of the first frame 20a along the x axis. Further, the third frame 20c extends in the negative direction along the x axis from the negative direction end of the second frame 20b along the y axis, and the fourth frame 20d connects the negative direction end of the third frame 20c along the x axis and the negative direction end of the first frame 20a along the x axis. The frames 20 bound the outer circumference of the solar cell module 100 and are made of a metal such as aluminum. The first frame 20a and the third frame 20c are longer than the second frame 20b and the fourth frame 20d, respectively, so that the solar cell module 100 has a rectangular shape longer in the x axis direction than in the y axis direction.

The first bridge wiring member 14a through the tenth bridge wiring member 14j extend in the x axis direction. The first bridge wiring member 14a through the fourth bridge wiring member 14d are provided on a line in the central portion of the solar cell module 100c along the y axis. A first region 90a is provided on the positive direction side along the y axis and a second region 90b is provided on the negative direction side along the y axis across a boundary defined by the first bridge wiring member 14a through the fourth bridge wiring member 14d. The first region 90a and the second region 90b each has a rectangular shape more elongated in the x axis direction than in the y axis direction. The fifth bridge wiring member 14e through the seventh bridge wiring member 14g are arranged on a line in the first region 90a toward the positive direction end of the solar cell module 100 along the y axis. Further, the eighth bridge wiring member 14h through the tenth bridge wiring member 14j are arranged on a line in the second region 90b toward the negative direction end of the solar cell module 100 along the y axis.

Each of the plurality of solar cells 10 absorbs incident light and generates photovoltaic power. In particular, the solar cell 10 generates an electromotive force from the light absorbed on the light receiving surface and also generates photovoltaic power from the light absorbed on the back surface. The solar cell 10 is formed by, for example, a semiconductor material such as crystalline silicon, gallium arsenide (GaAs), or indium phosphorus (InP). The structure of the solar cell 10 is not limited to any particular type. It is assumed that crystalline silicon and amorphous silicon are stacked by way of example. The solar cell 10 is a half-cut cell described above and has a rectangular shape more elongated in the x axis direction than in the y axis direction, but the shape of the solar cell 10 is not limited to this. A plurality of finger electrodes extending in the x axis direction in a mutually parallel manner are disposed on the light receiving surface and the back surface of each solar cell 10.

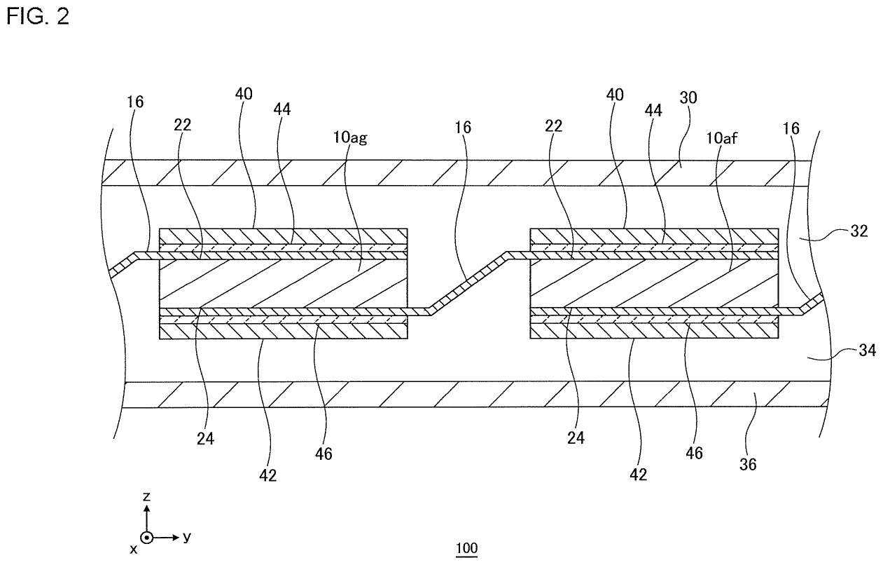

The plurality of solar cells 10 are arranged in a matrix on the x-y plane. In this case, four solar cells 10 are arranged in the y axis direction in the first region 90a. The finger electrode on the light receiving surface side of one of the two solar cells 10 adjacent to each other in the y axis direction and the finger electrode on the back surface side of the other solar cell are electrically connected by a cell wiring member (not shown). FIG. 2 is a cross sectional view of the solar cell module 100. FIG. 2 is a cross-sectional view along the y axis and is an A-A′ cross-sectional view of FIG. 1. The solar cell module 100 includes a 1-6th solar cell 10af, a 1-7th solar cell 10ag, cell wiring members 16, a first protection member 30, a first encapsulant 32, a second encapsulant 34, a second protection member 36, a light receiving surface side cell film 40, a back surface side cell film 42, a light receiving surface side adhesive 44, and a back surface side adhesive 46. The top of FIG. 2 corresponds to the light receiving surface side, and the bottom corresponds to the back surface side.

The first protection member 30 is disposed on the light receiving surface side of the solar cell module 100 and protects the surface of the solar cell module 100. Further, the solar cell module 100 is shaped in a rectangle bounded by the frames 20 on the x-y plane. The first protection member 30 is formed by using a translucent and water shielding glass, translucent plastic, etc. The first protection member 30 increases the mechanical strength of the solar cell module 100.

The first encapsulant 32 is stacked on the back surface side of the first protection member 30. The first encapsulant 32 is disposed between the first protection member 30 and the solar cell 10 and adhesively bonds the first protection member 30 and the solar cell 10. For example, a thermoplastic resin film of polyolefin, ethylene-vinyl acetate copolymer (EVA), polyvinyl butyral (PVB), polyimide, or the like may be used as the first encapsulant 32. A thermosetting resin may alternatively be used. The first encapsulant 32 is formed by a translucent sheet member having a surface of substantially the same dimension as the x-y plane in the first protection member 30.

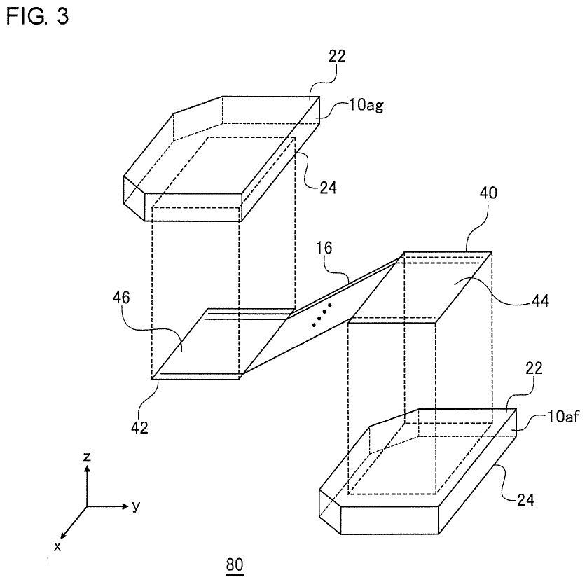

The 1-6th solar cell 10af and the 1-7th solar cell 10ag are stacked on the back surface side of the first protection member 30. The solar cells 10 are provided such that the light receiving surface 22 faces the positive direction side along the z axis and the back surface 24 faces the negative direction side along the z axis. When the light receiving surface 22 is referred to as the “first surface”, the back surface 24 is referred to as the “second surface”. The cell wiring members 16, the light receiving surface side adhesive 44, and the light receiving surface side cell film 40 are provided on the light receiving surface 22 of the solar cell 10, and the cell wiring members 16, the back surface side adhesive 46, and the back surface side cell film 42 are provided on the back surface 24 of the solar cell 10. FIG. 3 will be used to describe the above arrangement in the solar cell 10.

FIG. 3 is a perspective view showing the structure of a film 80 used in the solar cell module 100. The film 80 includes the cell wiring members 16, the light receiving surface side cell film 40, the back surface side cell film 42, the light receiving surface side adhesive 44, and the back surface side adhesive 46. The film 80 corresponds to the wire film described above, the light receiving surface side cell film 40 and the back surface side cell film 42 correspond to the transparent member described above, and the cell wiring members 16 correspond to the wires described above. The cell wiring members 16 each has a diameter of 100-500 μm, and, preferably, 300 μm, which is thinner than the width 1-2 mm of a tab wire commonly used in a solar cell module. Meanwhile, the number of cell wiring members 16 is 10-20, which is larger than the number of tab wires commonly used in a solar cell module. For example, the cell wiring members 16 extend in a cylindrical shape, and the side surface of the cylinder is coated by a solder.

The light receiving surface side cell film 40 is provided on the light receiving surface 22 side of one of the two adjacent solar cells 10, and, for example, the 1-6th solar cell 10af. The light receiving surface side cell film 40 is formed by a transparent resin film of, for example, polyethylene terephthalate (PET). The light receiving surface side cell film 40 has a rectangular shape smaller than the solar cell 10 on the x-y plane. The light receiving surface side adhesive 44 is provided on the surface of the light receiving surface side cell film 40 toward the 1-6th solar cell 10af, and the plurality of cell wiring members 16 are provided in the light receiving surface side adhesive 44. By attaching the light receiving surface side adhesive 44 on the light receiving surface 22 of the 1-6 solar cell 10af, the cell wiring members 16 are sandwiched between the light receiving surface side cell film 40 and the 1-6th solar cell 10af. For example, EVA is used for the light receiving surface side adhesive 44.

The back surface side cell film 42 is provided on the back surface 24 side of the other of the two adjacent solar cells 10, and, for example, the 1-7th solar cell 10ag. Like the light receiving surface side cell film 40, the back surface side cell film 42 is formed by a transparent resin film of, for example, PET. The back surface side cell film 42 has a rectangular shape smaller than the solar cell 10 on the x-y plane. The back surface side adhesive 46 is provided on the surface of the back surface side cell film 42 toward the 1-7th solar cell 10ag, and the plurality of cell wiring members 16 are provided in the back surface side adhesive 46. By attaching the back surface side adhesive 46 on the back surface 24 of the 1-7 solar cell 10ag, the cell wiring members 16 are sandwiched between the back surface side cell film 42 and the 1-7th solar cell 10ag. For example, EVA is used for the back surface side adhesive 46.

The film 80 configured as described above and the solar cell module 100 are manufactured separately. In manufacturing the solar cell module 100, the light receiving surface side adhesive 44 is provided on the light receiving surface 22 of the 1-6th solar cell 10af, and the back surface side adhesive 46 is provided on the back surface 24 of the 1-7th solar cell 10ag, as described above. By providing the adhesives in this way, the cell wiring members 16 electrically connects the finger electrode (not shown) on the light receiving surface 22 of the 1-6th solar cell 10af and the finger electrode (not shown) on the back surface 24 of the 1-7th solar cell 10ag. Reference is mad back to FIG. 2.

The light receiving surface side cell film 40 and the back surface side cell film 42 are equally provided in the other solar cells 10. The second encapsulant 34 is stacked on the back surface side of the first encapsulant 32. The second encapsulant 34 encapsulates the plurality of solar cells 10, the cell wiring members 16, the bridge wiring members 14, the light receiving surface side cell film 40, the back surface side cell film 42, etc., sandwiching them between the first encapsulant 32 and the second encapsulant 34. The same member as used for the first encapsulant 32 may be used for the second encapsulant 34. Alternatively, the second encapsulant 34 may be integrated with the first encapsulant 32 by heating the members in a laminate cure process.

The second protection member 36 is stacked on the back surface side of the second encapsulant 34 so as to face the first protection member 30. The second protection member 36 protects the back surface side of the solar cell module 100 as a back sheet. A resin film of, for example, PET, polytetrafluoroethylene (PTFE), etc., a stack film having a structure in which an Al foil is sandwiched by resin films of polyolefin, or the like is used as the second protection member 36. Reference is made back to FIG. 1.

As described above, the 1-1-st solar cell 10aa through the 1-4th solar cell 10ad arranged in the y axis direction are connected in series by the cell wiring members 16, and the 1-5th solar cell 10ae through the 1-8th solar cell 10ah are also connected in series by the cell wiring members 16. Further, the 1-4th solar cell cell 10ad and the 1-5th solar cell 10ae are connected to the fifth bridge wiring member 14e. As a result, electrical connection between the 1-1-st solar cell 10aa through the 1-4th solar cell 10ad, the fifth bridge wiring member 14e, and the 1-5th solar cell 10a e through the 1-8th solar cell 10ah forms the 1-1st solar cell string 12aa.

In the first region 90a, the 1-2nd solar cell string 12ab and the 1-3rd solar cell string 12ac are similarly formed, and the 1-1-st solar cell string 12aa through the 1-3 solar cell string 12ac are arranged on a line in the x axis direction. In the second region 90b, the 2-1-st solar cell string 12ba through the 2-3 solar cell string 12bc are similarly arranged on a line in the x axis direction. For example, the 2-1-st solar cell string 12ab is formed by electrical connection between the 2-1-st solar cell 10ba through the 2-4th solar cell 10bd, the eighth bridge wiring member 14h, and the 2-5th solar cell 10be through the 2-8th solar cell 10bh. The number of solar cells 10 included in one solar cell string is not limited to “8”, and the number of solar cell strings 12 is not limited to “6”. In other words, the solar cell module 100 need not have a rectangular shape more elongated in the x axis direction than in the y axis direction and may have a rectangular shape less elongated in the x axis direction than in the y axis direction depending on the number of solar cells 10 included in one solar cell string 12 or the number of solar cell strings 12. Alternatively, the solar cell module 100 may have a rectangular shape having the same length in the y axis direction and in the x axis direction.

The first bridge wiring member 14a through the fourth bridge wiring member 14d electrically connect the solar cell strings 12 in the first region 90a and the solar cell strings 12 in the second region 90b. For example, the first bridge wiring member 14a connect the 1-1-st solar cell 10aa of the 1-1-st solar cell string 12aa and the 2-1-st solar cell string 10ba of the 2-1-st solar cell string 12ba. Further, the second bridge wiring member 14b connects the 1-8th solar cell 10ah of the 1-1-st solar cell string 12aa and the 1-9th solar cell 10ai of the 1-2nd solar cell string 12ab in the first region 90a. Still further, the second bridge wiring member 14b connects the 2-8th solar cell 10bh of the 2-1st solar cell string 12ba and the 2-9th solar cell 10bi of the 2-2nd solar cell string 12bb in the second region 90b.

The 1-8th solar cell 10ah and the 1-9th solar cell 10ai are respectively provided on the side of the 1-1-st solar cell string 12aa and the 1-2 solar cell string 12ab toward the second bridge wiring member 14b, Further, 2-8th solar cell 10bh and the 2-9th solar cell 10bi are respectively provided on the side of the 2-1-st solar cell string 12ba and the 2-2 solar cell string 12bb toward the second bridge wiring member 14b, Still further, the 1-8th solar cell 10ah and the 2-8th solar cell 10b h face each other, sandwiching the second bridge wiring member 14b, and the 1-9th solar cell 10ai and the 2-9th solar cell 10bi also face each other, sandwiching the second bridge wiring member 14b. Similar connections are established in the third bridge wiring member 14c and the fourth bridge wiring member 14d.

This connects the 1-1-st solar cell string 12aa, the 1-2nd solar cell string 12ab, and the 1-3rd solar string 12ac in series. The connection may be referred to as “fist section”. The 2-1-st solar cell string 12ba, the 2-2nd solar cell string 12bb, and the 2-3rd solar string 12bc are also connected in series. The connection may be referred to as “second section”. Further, the first section and the second section are connected in parallel. A lead wiring member (not shown) is connected to the first bridge wiring member 14a and the fourth bridge wiring member 14d. The lead wiring member is a wiring member for retrieving the electric power generated in the plurality of solar cells 10 outside the solar cell module 100.

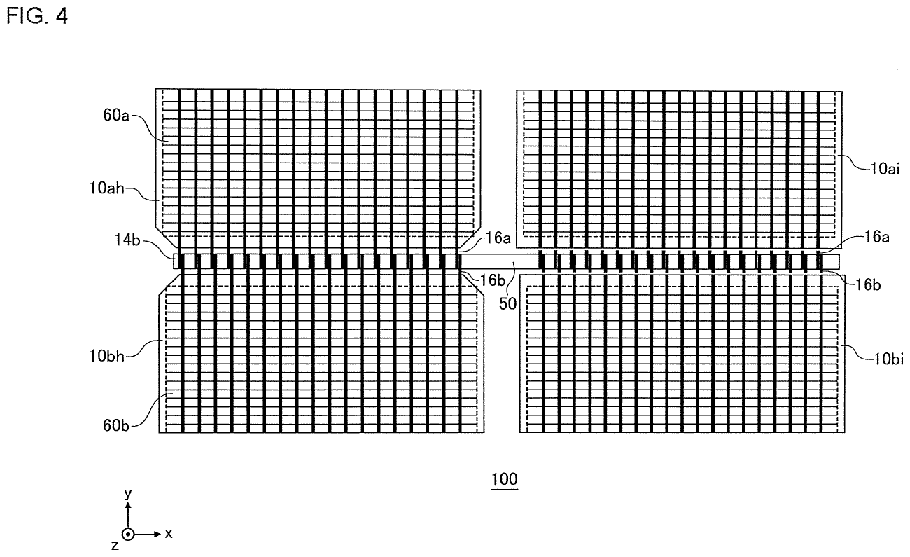

FIG. 4 is an enlarged plan view showing the structure of a portion of the solar cell module 100. The figure shows a portion of the 1-8th solar cell 10ah, the 1-9th solar cell 10ai, the 2-8th solar cell 10bh, the 2-9th solar cell 10bi, and the second bridge wiring member 14b of FIG. 1. A rectangular surface 50 having a length in the x axis direction and a width in the y axis direction is provided on the light receiving surface side of the second bridge wiring member 14b.

The light receiving surface side cell film 40 attached to the 1-8th solar cell 10ah is referred to as a first cell film 60a, and the cell wiring members 16 provided in the first cell film 60a are referred to as first cell wiring members 16a. Therefore, the plurality of first cell wiring members 16a are connected to the 1-8th solar cell 10ah by the first cell film 60a and extend from the 1-8th solar cell 10ah toward the second bridge wiring member 14b. Further, the light receiving surface side cell film 40 attached to the 2-8th solar cell 10bh is referred to as a second cell film 60b, and the cell wiring members 16 provided in the second cell film 60b are referred to as the second cell wiring members 16b. Therefore, the plurality of second cell wiring members 16b are connected to the 2-8th solar cell 10bh by the second cell film 60b and extend from the 2-8th solar cell 10bh toward the second bridge wiring member 14b.

Each of the plurality of first cell wiring members 16a extends on the surface 50 of the second bridge wiring member 14b toward the end facing the 2-8th solar cell 10bh and is, for example, soldered to the surface 50. Each of the plurality of second cell wiring members 16b extends on the surface 50 of the second bridge wiring member 14b toward the end facing the 1-8th solar cell 10ah and is, for example, soldered to the surface 50. Each of the plurality of first cell wiring member 16a and each of the plurality of second cell wiring members 16b are arranged on the surface 50 such that they are displaced from each other in the x axis direction and mutually overlap along the y axis direction. In other words, the plurality of first cell wiring members 16a and the plurality of second cell wiring members 16b are in mesh with each other in a comb tooth pattern on the surface 50 of the second bridge wiring member 14b.

The back surface side cell film 42 (not shown) is adhesively attached to the back surface side of the 1-9th solar cell 10ai, and the cell wiring members 16 are sandwiched between the 1-9th solar cell 10ai and the back surface side cell film 42. The back surface side cell film 42 adhesively attached to the 1-9th solar cell 10ai is also referred to as the first cell film 60a, and the cell wiring members 16 provided in the first cell film 60a are also referred to as the first cell wiring members 16a. Therefore, the plurality of first cell wiring members 16a are connected to the 1-9th solar cell 10ai by the first cell film 60a and extend from the 1-9th solar cell 10ai toward the second bridge wiring member 14b.

The back surface side cell film 42 (not shown) is also adhesively attached to the back surface side of the 2-9th solar cell 10bi, and the cell wiring members 16 are sandwiched between the 2-9th solar cell 10bi and the back surface side cell film 42. The back surface side cell film 42 adhesively attached to the 2-9th solar cell 10bi is also referred to as the second cell film 60b, and the cell wiring members 16 provided in the second cell film 60b are also referred to as the second cell wiring members 16b. Therefore, the plurality of second cell wiring members 16b are connected to the 2-9th solar cell 10bi by the second cell film 60b and extend from the 2-9th solar cell 10bi toward the second bridge wiring member 14b.

Each of the plurality of first cell wiring members 16a extends from the back surface side to the light receiving surface side, extends on the surface 50 of the second bridge wiring member 14b toward the end facing the 2-9th solar cell 10bi, and is connected to the surface 50. Each of the plurality of second cell wiring members 16b extends from the back surface side to the light receiving surface side, extends on the surface 50 of the second bridge wiring member 14b toward the end facing the 1-9th solar cell 10ai, and is connected to the surface 50. The arrangement of the plurality of first cell wiring members 16a and the plurality of second cell wiring members 16b on the surface 50 are as described above, and a description thereof is omitted. Connection like this between the cell wiring members 16 and the bridge wiring member 14 is equally established in the bridge wiring members 14 other than the second bridge wiring member 14b.

A description will now be given of a method of manufacturing the solar cell module 100.

(1) The film 80 shown in FIG. 3 is prepared to connect two adjacent solar cells 10. The solar cell string 12 is produced by aligning the light receiving surface side cell film 40 on one of the two adjacent solar cells and aligning the back surface side cell film 42 of the film 80 on the other of the two adjacent solar cells 10.

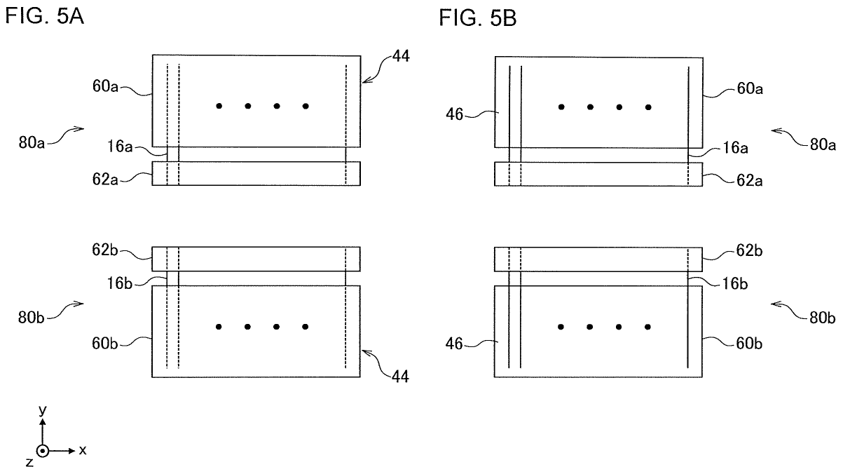

(2) The film 80 is prepared to connect the solar cell 10 provided at the end of the solar cell string 12 to the bridge wiring member 14. FIGS. 5A-5B are plan views showing the structure of the film 80 used in the solar cell module 100. FIG. 5A shows a first film 80a that should be adhesively attached to the 1-8th solar cell 10ah of FIG. 4 and a second film 80b that should be adhesively attached to the 2-8th solar cell 10bh. The first cell film 60a is provided toward the first end of the plurality of first cell wiring members 16a in the first film 80a, and a first wiring member film 62a is provided toward the second end opposite to the first end. The first wiring member film 62a has a size different from that of the light receiving surface side cell film 40 but is configured in a manner similar to the light receiving surface side cell film 40. The light receiving surface side adhesive 44 and the plurality of first cell wiring members 16a are provided on the back surface side of the first cell film 60a, and an adhesive (not shown) and the plurality of first cell wiring members 16a are provided on the back surface side of the first wiring member film 62a.

The second cell film 60b is provided toward the first end of the plurality of second cell wiring members 16b in the second film 80b, and a second wiring member film 62b is provided toward the second end opposite to the first end. The second wiring member film 62b is configured in a manner similar to the first wiring member film 62a. The light receiving surface side adhesive 44 and the plurality of second cell wiring members 16b are provided on the back surface side of the second cell film 60b, and an adhesive (not shown) and the plurality of second cell wiring members 16b are provided on the back surface side of the second wiring member film 62b. The first wiring member film 62a and the second wiring member film 62b are removed.

FIG. 5B shows the first film 80a that should be adhesively attached to the 1-9th solar cell 10ai of FIG. 4 and the second film 80b that should be adhesively attached to the 2-9th solar cell 10bi. The first cell film 60a is provided toward the first end of the plurality of first cell wiring members 16a in the first film 80a, and the first wiring member film 62a is provided toward the second end opposite to the first end. The back surface side adhesive 46 and the plurality of first cell wiring members 16a are provided on the light receiving surface side of the first cell film 60a, and an adhesive (not shown) and the plurality of first cell wiring members 16a are provided on the back surface side of the first wiring member film 62a.

The second cell film 60b is provided toward the first end of the plurality of second cell wiring members 16b in the second film 80b, and the second wiring member film 62b is provided toward the second end opposite to the first end. The back surface side adhesive 46 and the plurality of second cell wiring members 16b are provided on the light receiving surface side of the second cell film 60b, and an adhesive (not shown) and the plurality of second cell wiring members 16b are provided on the back surface side of the second wiring member film 62b. The first wiring member film 62a and the second wiring member film 62b are removed.

(3) By attaching the light receiving surface side adhesive 44 of the first cell film 60a of FIG. 5A to the light receiving surface 22 of the 1-8th solar cell 10ah, the first cell film 60a is attached to the 1-8th solar cell 10ah. By attaching the light receiving surface side adhesive 44 of the second cell film 60b to the light receiving surface 22 of the 2-8th solar cell 10bh, the second cell film 60b is attached to the 2-8th solar cell 10bh. By attaching the back surface side adhesive 46 of the first cell film 60a of FIG. 5B to the back surface 24 of the 1-8th solar cell 10ah, the first cell film 60a is attached to the 1-8th solar cell 10ah. By attaching the back surface side adhesive 46 of the second cell film 60b to the back surface 24 of the 2-8th solar cell 10bh, the second cell film 60b is attached to the 2-8th solar cell 10bh. A similar process is performed for the other solar cells 10. (2) and (3) may be reversed in the sequence.

(4) The second end of each of the plurality of first cell wiring members 16a and the second end of each of the plurality of second cell wiring members 16b of FIG. 5A are placed on the surface 50 of the second bridge wiring member 14b. Further, the second end of each of the plurality of first cell wiring members 16 and the second end of each of the plurality of second cell wiring members 16b are caused to be displaced from each other in the x axis direction and mutually overlap along the y axis direction. Further, the second end of each of the plurality of first cell wiring members 16a and the second end of each of the plurality of second cell wiring members 16b are soldered to the surface 50. As a result, the second end of each of the plurality of first cell wiring members 16a and the second end of each of the plurality of second cell wiring members 16b are connected to the surface 50 of the second bridge wiring member 14b. A similar process is performed for the other bridge wiring members 14.

(5) A stack is produced by layering the first protection member 30, the first encapsulant 32, the solar cell string 12, the second encapsulant 34, and the second protection member 36 in the stated order in the positive-to-negative direction along the z axis.

(6) A laminate cure process performed for the stack. In this process, air is drawn from the stack, and the stack is heated and pressurized so as to be integrated. In vacuum lamination in the laminate cure process, the temperature is set to about 100-170°.

According to the embodiment, the plurality of first cell wiring members 16a and the plurality of second cell wiring members 16b are connected to the surface of the bridge wiring member 14 such that the first cell wiring members 16a and the second cell wiring members 16b overlap along the second direction. Therefore, the area of contact between the cell wiring members 16 and the bridge wiring member 14 is increased when the solar cell 10 is connected to the bridge wiring member 14. Since the area of contact between the cell wiring members 16 and the bridge wiring member 14 is increased, the electrical resistance is inhibited from increasing. Since the electrical resistance is inhibited from increasing, the electrical property of the solar cell module 100 is improved. Since the area of contact between the cell wiring members 16 and the bridge wiring member 14 is increased, the strength of connection is inhibited from being reduced. Since the strength of connection is inhibited from being reduced, the reliability of the portion of connection is improved. Since a wire thinner than a tab wire is used for the cell wiring members 16, the impact on the appearance of the solar cell module 100 of a displacement in the position of the cell wiring members 16 in the solar cell string 12 in the first region 90a and the solar cell string 12 in the second region 90b is reduced.

Further, since the plurality of first cell wiring members 16a are connected to the first solar cell 10 by the first cell film 60a and the plurality of second cell wiring members 16b are connected to the second solar cell 10 by the second cell film 60b, the manufacturing steps are simplified. Further, since the plurality of first cell wiring members 16a extend on the surface 50 of the bridge wiring member 14 as far as the end facing the second solar cell 10 and the plurality of second cell wiring members 16 extend on the surface of the bridge wiring member 14 as far as the end facing the first solar cell 10, the area of contact is increased. Further, since at least one of the first wiring member film 62a and the second wiring member film 62b is removed, the second end of the plurality of first cell wiring members 16a and the second end of the plurality of second cell wiring members 16b can be attached to the surface 50 of the bridge wiring member 14.

One embodiment of the disclosure is summarized below. A solar cell module 100 according to an embodiment of the present disclosure includes: a bridge wiring member 14 that extends in a first direction; a first solar cell string 12 that extends, of a first region 90a and a second region 90b separated and interfaced by the bridge wiring member 14, in the first region 90a and in a second direction different from the first direction; and a second solar cell string 12 that extends in the second region 90b and in the second direction. The bridge wiring member 14 includes a surface 50 having a length in the first direction and a width in the second direction. The first solar cell string 12 includes a first solar cell 10 provided on a side of the bridge wiring member 14. The second solar cell string 12 includes a second solar cell 10 provided on a side of the bridge wiring member 14 and facing the first solar cell 10, sandwiching the bridge wiring member 14. A plurality of first cell wiring members 16a extending from the first solar cell 10 toward the bridge wiring member 14 and a plurality of second cell wiring members 16b extending from the second solar cell 10 toward the bridge wiring member 14 are connected to the surface 50 of the bridge wiring member 14 such that the plurality of first cell wiring members 16a and the plurality of second cell wiring members 16b mutually overlap along the second direction.

The plurality of first cell wiring members 16a are connected to the first solar cell 10 by a first cell film 60a, and the plurality of second cell wiring members 16 are connected to the second solar cell 10 by a second cell film 60b.

The plurality of first cell wiring members 16a extend on the surface of the bridge wiring member 14 as far as an end facing the second solar cell 10, and the plurality of second cell wiring members 16b extend on the surface of the bridge wiring member 14 as far as an end facing the first solar cell 10.

The plurality of first cell wiring members 16a extend on the surface 50 of the bridge wiring member 14 as far as a position between an end facing the first solar cell 10 and an end facing the second solar cell 10, and the plurality of second cell wiring members 16b extend on the surface of the bridge wiring member 14 as far as a position between an end facing the first solar cell 10 and an end facing the second solar cell 10.

Another embodiment of the present disclosure relates to a manufacturing method. The method is for manufacturing a solar cell module 100 including: a bridge wiring member 14 that extends in a first direction; a first solar cell string 12 that extends, of a first region 90a and a second region 90b separated and interfaced by the bridge wiring member 14, in the first region 90a and in a second direction different from the first direction; and a second solar cell string 12 that extends in the second region 90b and in the second direction. The bridge wiring member 14 includes a surface 50 having a length in the first direction and a width in the second direction. The first solar cell string 12 includes a first solar cell 10 provided on a side of the bridge wiring member 14. The second solar cell string 12 includes a second solar cell 10 provided on a side of the bridge wiring member 14 and facing the first solar cell 10, sandwiching the bridge wiring member 14. The method includes: removing at least one of a first film 80a and a second film 80b, the first film 80a being configured by attaching a first cell film 60a at a first end of the plurality of first cell wiring members 16a and attaching a first wiring member film 62a at a second end of the plurality of first cell wiring members 16a, and the second film 80b being configured by attaching a second cell film 60b at a first end of the plurality of second cell wiring members 16b and attaching a second wiring member film 62b at a second end of the plurality of second cell wiring members 16b; attaching the first cell film 60a to the first solar cell 10 and attaching the second cell film 60b to the second solar cell 10; and connecting a second end of the plurality of first cell wiring members 16a and a second end of the plurality of second cell wiring members 16b to a surface 50 of the bridge wiring member 14 such that the plurality of first cell wiring members 16a and the plurality of second cell wiring members 16b mutually overlap along the second direction.

### Embodiment 2

A description will now be given of embodiment 2. Like embodiment 1, embodiment 2 relates to a solar cell module in which a plurality of solar cells are arranged in a matrix. The plurality of first cell wiring members 16a and the plurality of second cell wiring members 16b are in mesh with each other in a comb tooth pattern on the surface 50 of the second bridge wiring member 14b. In embodiment 1, the first wiring member film 62a and the second wiring member film 62b are removed. In embodiment 2, one of these is maintained. Therefore, the plurality of first cell wiring member 16a and the plurality of second cell wiring members 16b are provided between the wiring member film 62 that remains and the bridge wiring member 14. The solar cell module 100 according to embodiment 2 is of the same type as that of FIG. 1 and FIG. 2, and the film 80 is of the same type as shown in FIG. 3. The following description concerns a difference from the foregoing embodiments.

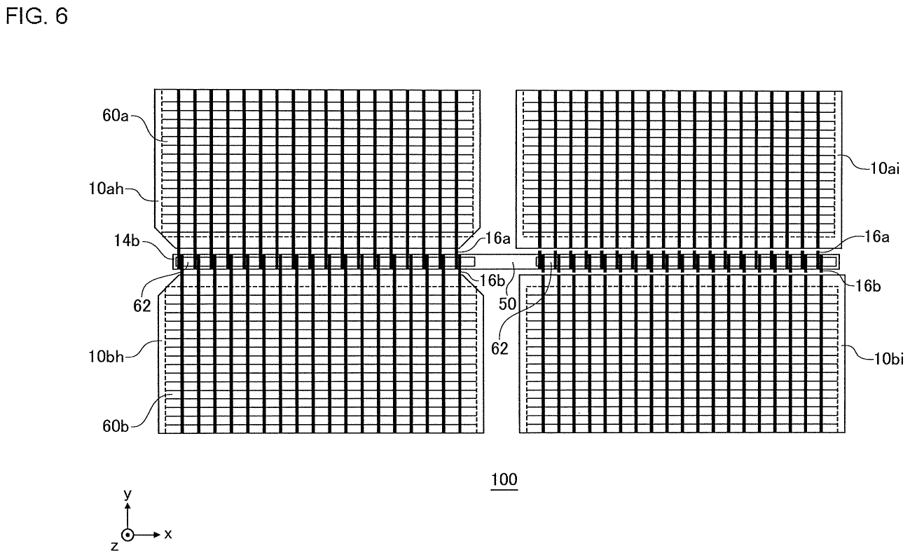

FIG. 6 is an enlarged plan view showing the structure of a portion of the solar cell module 100. The appearance is similar to that of FIG. 4. As in the foregoing embodiment, the plurality of first cell wiring members 16a from the 1-8th solar cell 10ah extend toward the second bridge wiring member 14b, and the plurality of second cell wiring members 16b from the 2-8th solar cell 10bh extend toward the second bridge wiring member 14b. Further, each of the plurality of first cell wiring members 16a and each of the plurality of second cell wiring members 16b are arranged on the surface 50 such that they are displaced from each other in the x axis direction and mutually overlap along the y axis direction.

In embodiment 2, the wiring member film 62 is provided on the surface 50 of the second bridge wiring member 14b so as to cover the plurality of first cell wiring members 16a and the plurality of second cell wiring members 16b. In other words, the plurality of first cell wiring member 16a and the plurality of second cell wiring members 16b are provided between the surface 50 of the second bridge wiring member 14b and the wiring member film 62. It can be said that the plurality of first cell wiring member 16a and the plurality of second cell wiring members 16b are connected to the second bridge wiring member 14b by the wiring member film 62.

The plurality of first cell wiring members 16a from the 1-9th solar cell 10a i, the plurality of second cell wiring members 16b from the 2-9th solar cell 10bi, the second bridge wiring member 14b, and the wiring member film 62 are similarly configured. Connection like this between the cell wiring members 16, the bridge wiring member 14, and the wiring member film 62 is equally established in the bridge wiring members 14 other than the second bridge wiring member 14b.

A description will now be given of a method of manufacturing the solar cell module 100. A description of those steps that are identical to the steps of embodiment 1 will be omitted.

(2) One of the first wiring member film 62a and the second wiring member film 62b of FIG. 5A is removed. It is assumed here that the first wiring member film 62a is maintained. One of the first wiring member film 62a and the second wiring member film 62b of FIG. 5B is removed. It is also assumed here that the first wiring member film 62a is maintained.

(4) The second end of each of the plurality of second cell wiring member 16b of FIG. 5A is placed on the surface 50 of the second bridge wiring member 14b. In this state, the second end of each of the plurality of first cell wiring members 16a is placed on the surface 50 of the second bridge wiring member 14b such that the second end of each of the plurality of first cell wiring members 16a and the second end of each of the plurality of second cell wiring members 16b are displaced in the x axis direction and mutually overlap along the y axis direction. As a result, the wiring member film 62 covering the plurality of first cell wiring members 16a is provided on the surface 50 of the second bridge wiring member 14b such that the wiring member film 62 also covers the plurality of second cell wiring members 16b. A similar process is performed for the other bridge wiring members 14.

According to this embodiment, the plurality of first cell wiring members 16a and the plurality of second cell wiring members 16b are connected to the bridge wiring member 14 by the wiring member film 62 so that the strength of connection is increased. Further, the plurality of first cell wiring members 16a and the plurality of second cell wiring members 16b are connected to the bridge wiring member 14 by the wiring member film 62 so that the steps of manufacturing are simplified.

One embodiment of the disclosure is summarized below. The plurality of first cell wiring members 16a and the plurality of second cell wiring members 16b may be connected to the bridge wiring member 14 by a wiring member film 62.

### Embodiment 3

A description will now be given of embodiment 3. As in the foregoing embodiments, embodiment 3 relates to a solar cell module in which a plurality of solar cells are arranged in a matrix. The plurality of first cell wiring members 16a and the plurality of second cell wiring members 16b are in mesh with each other in a comb tooth pattern on the surface 50 of the second bridge wiring member 14b. The plurality of first cell wiring members 16a and the plurality of second cell wiring members 16b described so far have a substantially straight shape along the y axis on the x-y plane. Meanwhile, the plurality of first cell wiring members 16a and the plurality of second cell wiring members 16b according to embodiment 3 have a bent shape. The solar cell module 100 according to embodiment 3 is of the same type as that of FIG. 1 and FIG. 2, and the film 80 is of the same type as shown in FIG. 3. The following description concerns a difference from the foregoing embodiments.

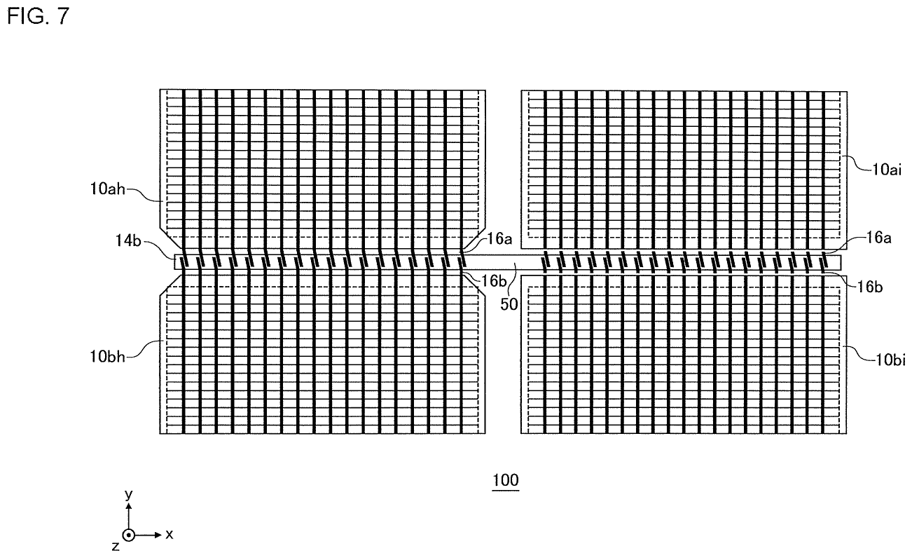

FIG. 7 is an enlarged plan view showing the structure of a portion of the solar cell module 100. The appearance is similar to that of FIG. 4. As in the foregoing embodiments, the plurality of first cell wiring members 16a from the 1-8th solar cell 10ah extend toward the second bridge wiring member 14b, and the plurality of second cell wiring members 16b from the 2-8th solar cell 10bh extend toward the second bridge wiring member 14b. The plurality of first cell wiring members 16a are bent on the surface 50 of the second bridge wiring member 14b such that the further in the negative direction along the y axis, the further the first cell wiring members 16a extend away from the bend in the positive direction of the x axis. The plurality of second cell wiring members 16b are bent on the surface 50 of the second bridge wiring member 14b such that the further in the positive direction along the y axis, the further the second cell wiring members 16b extend away from the bend in the negative direction of the x axis. Each of plurality of first cell wiring members 16a and each of the plurality of second cell wiring members 16b are provided substantially parallel on the surface 50 of the second bridge wiring member 14b. The plurality of first cell wiring members 16a from the 1-9th solar cell 10ai and the plurality of second cell wiring members 16b from the 2-9th solar cell 19bi are similarly configured. Connection like this between the cell wiring members 16 and the bridge wiring member 14 is equally established in the first bridge wiring members 14a, the third bridge wiring member 14c, and the fourth bridge wiring member 14d.

According to this embodiment, the plurality of first cell wiring members 16a and the plurality of second cell wiring members 16b are bent on the surface 50 of the bridge wiring member 14 so that the cell wiring members 16 on the solar cell 10 in the first region 90a are aligned with the solar cell 10 in the second region 90b. Since the cell wiring members 16 in the solar cells 10 are aligned, the aesthetic appearance of the solar cell module 100 is improved.

One embodiment of the disclosure is summarized below. The plurality of first cell wiring members 16a may be bent on the surface 50 of the bridge wiring member 14, the plurality of second cell wiring members 16b are bent on the surface 50 of the bridge wiring member 14, and the plurality of first cell wiring members 16a and the plurality of second cell wiring members 16b may be arranged on the surface 50 of the bridge wiring member 14.

Described above is an explanation based on an exemplary embodiment. The embodiment is intended to be illustrative only and it will be understood by those skilled in the art that various modifications to constituting elements and processes could be developed and that such modifications are also within the scope of the present disclosure.

Embodiment 1 and Embodiment 2 may be combined. According to this variation, the benefit from the combination is obtained.

In embodiments 1 through 3, the film 80 is used. Alternatively, however, the film 80 may not be used, and adjacent solar cells 10 may be connected by a cell wiring member 16 like a tab wire. In that case, the cell wiring member 16 may not be a wire. According to this variation, the flexibility in the configuration is improved.

In embodiments 1 through 3, the plurality of first cell wiring members 16a from the 1-8th solar cell 10ah extend on the surface 50 of the second bridge wiring member 14b as far as the end facing the 2-8th solar cell 10bh. Further, the plurality of second cell wiring members 16b from the 2-8th solar cell 10bh extend on the surface 50 of the second bridge wiring member 14b as far as the end facing the 1-8th solar cell 10ah. Alternatively, however, each of the the plurality of first cell wiring members 16a may extend on the surface 50 of the second bridge wiring member 14b as far as a position between the end facing the 1-8th solar cell 10ah and the end facing the 2-8th solar cell 10bh. Further, each of the the plurality of second cell wiring members 16b may extend on the surface 50 of the second bridge wiring member 14b as far as a position between the end facing the 1-8th solar cell 10ah and the end facing the 2-8th solar cell 10bh. The same is true of the other cell wiring members 16. According to this variation, the flexibility in the configuration is improved.

In embodiment 2, one of the first wiring member film 62a and the second wiring member film 62b is removed. Alternatively, however, a portion of the first wiring member film 62a may be removed, and a portion of the second wiring member film 62b may be removed. The portion of the first wiring member film 62a that remains and the portion of the second wiring member film 62b that remains are combined on the surface 50 of the second bridge wiring member 14b to from the wiring member film 62 of FIG. 6. According to this variation, the flexibility in the configuration is improved.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a bridge wiring member that extends in a first direction;
a first solar cell string that extends, of a first region and a second region separated and interfaced by the bridge wiring member, in the first region and in a second direction different from the first direction; and
a second solar cell string that extends in the second region and in the second direction, wherein
the bridge wiring member includes a surface having a length in the first direction and a width in the second direction,
the first solar cell string includes a first solar cell provided on a side of the bridge wiring member,
the second solar cell string includes a second solar cell provided on a side of the bridge wiring member and facing the first solar cell, sandwiching the bridge wiring member, and
a plurality of first cell wiring members extending from the first solar cell toward the bridge wiring member and a plurality of second cell wiring members extending from the second solar cell toward the bridge wiring member are connected to the surface of the bridge wiring member such that the plurality of first cell wiring members and the plurality of second cell wiring members mutually overlap along the second direction.

2. The solar cell module according to claim 1, wherein
the plurality of first cell wiring members are connected to the first solar cell by a first cell film, and
the plurality of second cell wiring members are connected to the second solar cell by a second cell film.

3. The solar cell module according to claim 1, wherein
the plurality of first cell wiring members extend on the surface of the bridge wiring member as far as an end facing the second solar cell, and
the plurality of second cell wiring members extend on the surface of the bridge wiring member as far as an end facing the first solar cell.

4. The solar cell module according to claim 2, wherein
the plurality of first cell wiring members extend on the surface of the bridge wiring member as far as an end facing the second solar cell, and
the plurality of second cell wiring members extend on the surface of the bridge wiring member as far as an end facing the first solar cell.

5. The solar cell module according to claim 1, wherein
the plurality of first cell wiring members extend on the surface of the bridge wiring member as far as a position between an end facing the first solar cell and an end facing the second solar cell, and
the plurality of second cell wiring members extend on the surface of the bridge wiring member as far as a position between an end facing the first solar cell and an end facing the second solar cell.

6. The solar cell module according to claim 2, wherein
the plurality of first cell wiring members extend on the surface of the bridge wiring member as far as a position between an end facing the first solar cell and an end facing the second solar cell, and
the plurality of second cell wiring members extend on the surface of the bridge wiring member as far as a position between an end facing the first solar cell and an end facing the second solar cell.

7. The solar cell module according to claim 1, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

8. The solar cell module according to claim 2, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

9. The solar cell module according to claim 3, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

10. The solar cell module according to claim 4, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

11. The solar cell module according to claim 5, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

12. The solar cell module according to claim 6, wherein
the plurality of first cell wiring members are bent on the surface of the bridge wiring member,
the plurality of second cell wiring members are bent on the surface of the bridge wiring member, and
the plurality of first cell wiring members and the plurality of second cell wiring members are arranged on the surface of the bridge wiring member.

13. The solar cell module according to claim 1, wherein
the plurality of first cell wiring members and the plurality of second wiring members are connected to the bridge wiring member by a wiring member film.

14. A method of manufacturing a solar cell module, the solar cell module including:
a bridge wiring member that extends in a first direction;
a first solar cell string that extends, of a first region and a second region separated and interfaced by the bridge wiring member, in the first region and in a second direction different from the first direction; and
a second solar cell string that extends in the second region and in the second direction, wherein
the bridge wiring member includes a surface having a length in the first direction and a width in the second direction,
the first solar cell string includes a first solar cell provided on a side of the bridge wiring member,
the second solar cell string includes a second solar cell provided on a side of the bridge wiring member and facing the first solar cell, sandwiching the bridge wiring member, and
removing at least one of a first film and a second film, the first film being configured by attaching a first cell film at a first end of the plurality of first cell wiring members and attaching a first wiring member film at a second end of the plurality of first cell wiring members, and the second film being configured by attaching a second cell film at a first end of the plurality of second cell wiring members and attaching a second wiring member film at a second end of the plurality of second cell wiring members;
attaching the first cell film to the first solar cell and attaching the second cell film to the second solar cell; and
connecting a second end of the plurality of first cell wiring members and a second end of the plurality of second cell wiring members to a surface of the bridge wiring member such that the plurality of first cell wiring members and the plurality of second cell wiring members mutually overlap along the second direction.
